(19) United States
(12) Patent Application Publication
(10) Pub. No.: US 2023/0290832 A1
(43) Pub. Date: Sep. 14, 2023

(54) SEMICONDUCTOR DEVICE

(71) Applicants: FLOSFIA INC., Kyoto (JP); DENSO CORPORATION, Aichi (JP)

(72) Inventors: Yasushi HIGUCHI, Kyoto (JP); Masahiro SUGIMOTO, Kyoto (JP); Takashi SHINOHE, Kyoto (JP); Isao TAKAHASHI, Kyoto (JP); Hideo MATSUKI, Aichi (JP); Fusao HIROSE, Aichi (JP)

(21) Appl. No.: 18/133,246

(22) Filed: Apr. 11, 2023

Related U.S. Application Data
(63) Continuation-in-part of application No. PCT/JP2021/037640, filed on Oct. 11, 2021.

(30) Foreign Application Priority Data
Oct. 12, 2020 (JP) 2020-171865
Oct. 12, 2020 (JP) 2020-171866
Oct. 12, 2020 (JP) 2020-171867

(51) Int. Cl. H01L 29/12; H01L 29/06

(52) U.S. Cl. CPC H01L 29/12; H01L 29/06; H01L 29/7802

(57) ABSTRACT

Provided is a semiconductor device, including: a gate electrode having at least a part buried in a semiconductor layer; a deep p layer having at least a part buried in the semiconductor layer to a same depth as a buried lower end portion of the gate electrode or a position deeper than the buried lower end portion; and a channel layer, wherein: the deep p layer is formed by a crystalline oxide semiconductor; and a carrier concentration of the deep p layer is higher than a carrier concentration of the channel layer.

### CROSS REFERENCE TO RELATED APPLICATION

This application is a continuation-in-part application of International Patent Application No. PCT/JP2021/037640 (Filed on Oct. 11, 2021), which claims the benefit of priority from Japanese Patent Application Nos. 2020-171865 (filed on Oct. 12, 2020), 2020-171866 (filed on Oct. 12, 2020), and 2020-171867 (filed on Oct. 12, 2020).

The entire contents of the above applications, which the present application is based on, are incorporated herein by reference.

### 1. FIELD OF THE INVENTION

The present disclosure relates to a semiconductor device suitable for use as a power device and the like and a semiconductor system including the same.

### 2. DESCRIPTION OF THE RELATED ART

A semiconductor device using gallium oxide (Ga₂O₃) having a great band gap has been gathering attention as a next-generation crystalline oxide semiconductor material capable of realizing high voltage resistance, low loss, and high thermal resistance. The semiconductor device including a crystalline oxide semiconductor has been expected to be applied to a power semiconductor device such as an inverter as a switching element. Application as a light receiving/emitting apparatus such as an LED and a sensor has also been expected due to the wide band gap.

It has been known that there are five crystal structures, that is, α, β, γ, δ, and ε in gallium oxide. Several examinations have currently been made regarding the film formation of a crystalline oxide semiconductor film containing gallium oxide and/or mixed crystal thereof including the film formation of a crystalline semiconductor having a corundum structure.

For example, it is known that it becomes possible to perform band gap control by obtaining mixed crystal formed by mixing each of indium or aluminum or a combination of indium and aluminum with gallium oxide, and gallium oxide is known as an InAlGaO-based semiconductor. Here, InAlGaO-based semiconductors indicate In_{X}Al_{Y}Ga_{Z}O₃ (0≤X≤2, 0≤Y≤2, 0≤Z≤2, X+Y+Z=1.5 to 2.5) and may be regarded as a family of materials including gallium oxide.

A semiconductor device containing gallium oxide is capable of realizing high voltage resistance, low loss, and high thermal resistance.

### SUMMARY OF THE INVENTION

According to an example of the present disclosure, there is provided a semiconductor device, including: a gate electrode having at least a part buried in a semiconductor layer; a deep p layer having at least a part buried in the semiconductor layer to a same depth as a buried lower end portion of the gate electrode or a position deeper than the buried lower end portion; and a channel layer, wherein: the deep p layer is formed by a crystalline oxide semiconductor; and a carrier concentration of the deep p layer is higher than a carrier concentration of the channel layer.

According to an example of the present disclosure, there is provided a semiconductor device, including: a gate electrode having at least a part buried in a semiconductor layer; a deep p layer having at least a part buried in the semiconductor layer to a same depth as a buried lower end portion of the gate electrode or a position deeper than the buried lower end portion; and a channel layer, wherein: a breakdown field strength of the deep p layer is 5 MV/cm or more; and a carrier concentration of the deep p layer is higher than a carrier concentration of the channel layer.

According to an example of the present disclosure, there is provided a semiconductor device, including: a gate insulating film and a gate electrode each having at least a part buried in an n-type semiconductor layer; a first deep p layer and a second deep p layer each having at least a part buried in the semiconductor layer to a same depth as a buried lower end portion of the gate electrode or a position deeper than the buried lower end portion; and a channel layer, wherein: the gate insulating film and the gate electrode are provided on an upper side between the first deep p layer and the second deep p layer; both of the deep p layers are formed by a crystalline oxide semiconductor; and a carrier concentration of each of the deep p layers is higher than a carrier concentration of the channel layer.

Thus, the semiconductor device of the present disclosure has an efficient electric field relaxation effect with respect to the crystalline oxide semiconductor layer and exhibits an excellent semiconductor property.

### BRIEF DESCRIPTION OF THE DRAWINGS

FIG. 1 is a schematic perspective cross-sectional view of a suitable semiconductor device in the present disclosure.

FIG. 2 shows an evaluation result of a simulation for the heat distribution around a gate electrode generated when current is applied to the semiconductor device in FIG. 1.

FIG. 3 is a perspective cross-sectional view schematically illustrating one suitable example of the semiconductor device in the present disclosure.

FIG. 4 is a diagram schematically illustrating one suitable example of a power source system.

FIG. 5 is a diagram schematically illustrating one suitable example of a power source circuit diagram of a power source apparatus.

FIG. 6 is a diagram schematically illustrating one suitable example of a power source circuit diagram of the power source apparatus.

FIG. 7 is a schematic view of a film formation apparatus (mist CVD apparatus) used in the formation of a crystalline oxide semiconductor layer.

FIG. 8 is a schematic view of the film formation apparatus (mist CVD apparatus) used in the formation of the crystalline oxide semiconductor layer.

FIG. 9 is a view schematically illustrating one suitable example of a power card.

FIG. 10 is a perspective cross-sectional view schematically illustrating one suitable example of the semiconductor device having a heat release structure.

FIG. 11 is a view schematically illustrating a cross-section of the semiconductor device in FIG. 10.

FIG. 12 is a perspective cross-sectional view schematically illustrating one suitable example of the semiconductor device having a heat release structure.

FIG. 13 is a view schematically illustrating a cross-section of the semiconductor device in FIG. 12.

FIG. 14 is a perspective cross-sectional view schematically illustrating one suitable example of the semiconductor device having a heat release structure.

FIG. 15 is a view schematically illustrating a cross-section of the semiconductor device in FIG. 14.

FIG. 16 is a perspective cross-sectional view schematically illustrating one suitable example of the semiconductor device having a heat release structure.

FIG. 17 is a view schematically illustrating a cross-section of the semiconductor device in FIG. 16.

### DETAILED DESCRIPTION

The inventors of the present disclosure have found out that a semiconductor device including: a laminated body including a crystalline oxide semiconductor layer containing gallium oxide or mixed crystal of gallium oxide; a gate electrode having at least a part buried in the laminated body; a deep p layer having at least a part buried in the semiconductor layer to a same depth as a buried lower end portion of the gate electrode or a position deeper than the buried lower end portion; and a channel layer is capable of exhibiting an extremely efficient electric field relaxation effect with respect to a semiconductor layer of the crystalline oxide semiconductor and causing a semiconductor property of the crystalline oxide semiconductor to be excellent. In the semiconductor device, the deep p layer is formed by a crystalline oxide semiconductor, and a carrier concentration of the deep p layer is higher than a carrier concentration of the channel layer.

Embodiments of the present disclosure will be described below with reference to the accompanying drawings. In the following description, the same parts and components are designated by the same reference numerals. The present embodiment includes, for example, the following disclosures.

### Structure 1

A semiconductor device, including: a gate electrode having at least a part buried in a semiconductor layer; a deep p layer having at least a part buried in the semiconductor layer to a same depth as a buried lower end portion of the gate electrode or a position deeper than the buried lower end portion; and a channel layer, wherein: the deep p layer is formed by a crystalline oxide semiconductor; and a carrier concentration of the deep p layer is higher than a carrier concentration of the channel layer.

### Structure 2

The semiconductor device according to [Structure 1], wherein a breakdown field strength of the crystalline oxide semiconductor is 5 MV/cm or more.

### Structure 3

The semiconductor device according to [Structure 1] or [Structure 2], wherein the crystalline oxide semiconductor has a corundum structure or a β-gallia structure.

### Structure 4

The semiconductor device according to any of [Structure 1] to [Structure 3], wherein the crystalline oxide semiconductor is gallium oxide or mixed crystal of gallium oxide.

### Structure 5

The semiconductor device according to any of [Structure 1] to [Structure 4], wherein the carrier concentration of the deep p layer is 1×10¹⁷/cm³ or more.

### Structure 6

The semiconductor device according to any of [Structure 1] to [Structure 5], wherein the semiconductor layer is an n-type semiconductor layer.

### Structure 7

The semiconductor device according to any of [Structure 1] to [Structure 6], wherein the semiconductor layer is a crystalline oxide semiconductor layer.

### Structure 8

The semiconductor device according to any of [Structure 1] to [Structure 7], wherein a breakdown field strength of the semiconductor layer is 5 MV/cm or more.

### Structure 9

The semiconductor device according to any of [Structure 1] to [Structure 8], wherein the semiconductor layer has a corundum structure or a β-gallia structure.

### Structure 10

The semiconductor device according to any of [Structure 1] to [Structure 9], wherein the semiconductor layer contains gallium oxide or mixed crystal of gallium oxide.

### Structure 11

A semiconductor device, including: a gate electrode having at least a part buried in a semiconductor layer; a deep p layer having at least a part buried in the semiconductor layer to a same depth as a buried lower end portion of the gate electrode or a position deeper than the buried lower end portion; and a channel layer, wherein: a breakdown field strength of the deep p layer is 5 MV/cm or more; and a carrier concentration of the deep p layer is higher than a carrier concentration of the channel layer.

### Structure 12

The semiconductor device according to any of [Structure 1] to [Structure 11], wherein the semiconductor layer has a thickness of 30 µm or less.

### Structure 13

The semiconductor device according to any of [Structure 1] to [Structure 12], wherein at least a part of a heat release portion is provided in a depth position of the buried lower end portion of the deep p layer in the semiconductor layer.

### Structure 14

A semiconductor device, including: a gate insulating film and a gate electrode each having at least a part buried in an n-type semiconductor layer; a first deep p layer and a second deep p layer each having at least a part buried in the semiconductor layer to a same depth as a buried lower end portion of the gate electrode or a position deeper than the buried lower end portion; and a channel layer, wherein: the gate insulating film and the gate electrode are provided on an upper side between the first deep p layer and the second deep p layer; both of the deep p layers are formed by a crystalline oxide semiconductor; and a carrier concentration of each of the deep p layers is higher than a carrier concentration of the channel layer.

### Structure 15

The semiconductor device according to any of [Structure 1] to [Structure 14] that is a normally-off-type semiconductor device.

### Structure 16

The semiconductor device according to [Structure 15] that is a power device.

### Structure 17

The semiconductor device according to any of [Structure 1] to [Structure 15] that is a power module, an inverter, or a converter.

### Structure 18

The semiconductor device according to any of [Structure 1] to [Structure 15] that is a power card.

### Structure 19

A semiconductor system, including a semiconductor device, wherein the semiconductor device is the semiconductor device according to any of [Structure 1] to [Structure 18].

A semiconductor device of the present disclosure is a semiconductor device including: a gate electrode having at least a part buried in a semiconductor layer; a deep p layer having at least a part buried in the semiconductor layer to a same depth as a buried lower end portion of the gate electrode or a position deeper than the buried lower end portion; and a channel layer. In the semiconductor device, the deep p layer is formed by a crystalline oxide semiconductor, and a carrier concentration of the deep p layer is higher than a carrier concentration of the channel layer.

A semiconductor device according to another embodiment of the present disclosure is a semiconductor device including: a gate electrode having at least a part buried in a semiconductor layer; a deep p layer having at least a part buried in the semiconductor layer to a same depth as a buried lower end portion of the gate electrode or a position deeper than the buried lower end portion; and a channel layer. In the semiconductor device, a breakdown field strength of the deep p layer is 5 MV/cm or more, and a carrier concentration of the deep p layer is higher than a carrier concentration of the channel layer. By configurations as above, it becomes possible to provide a semiconductor device having an efficient electric field relaxation effect capable of withstanding high field strength.

The expression of “the buried lower end portion of the gate electrode” means all or a part of the bottom of the gate electrode. The gate electrode is not particularly limited as long as the electrode is capable of controlling the flow of a main current, and the gate electrode includes a semiconductor region, a diffusion region, an electrode, and the like.

The material of the gate electrode is not particularly limited as long as the material is usable as the gate electrode, and the material may be a conductive inorganic material or a conductive organic material. In the present disclosure, it is preferred that the material of the gate electrode be metal, metal compound, metal oxide, or metal nitride. Examples of the metal suitably include at least one type of metal and the like selected from group 4 to group 11 in the periodic table. Examples of metal in group 4 in the periodic table include titanium (Ti), zirconium (Zr), hafnium (Hf), and the like. Examples of metal in group 5 in the periodic table include vanadium (V), niobium (Nb), tantalum (Ta), and the like. Examples of metal in group 6 in the periodic table include one type of two or more types of metal and the like selected from chromium (Cr), molybdenum (Mo), tungsten (W), and the like. Examples of metal in group 7 in the periodic table include manganese (Mn), technetium (Tc), rhenium (Re), and the like. Examples of metal in group 8 in the periodic table include iron (Fe), ruthenium (Ru), osmium (Os), and the like. Examples of metal in group 9 in the periodic table include cobalt (Co), rhodium (Rh), iridium (Ir), and the like. Examples of metal in group 10 in the periodic table include nickel (Ni), palladium (Pd), platinum (Pt), and the like. Examples of metal in group 11 in the periodic table include copper (Cu), silver (Ag), gold (Au), and the like.

Examples of formation means for the gate electrode include well-known means and the like, and more specifically include a dry method, a wet method, and the like. Examples of the dry method include well-known means such as spattering, vacuum deposition, and CVD. Examples of the wet method include screen printing, die coating, and the like.

The channel layer is not particularly limited as long as a channel is formed in a side wall of the gate electrode in a direct manner or via another layer. In the present disclosure, it is preferred that a part or all of the channel layer include a p-type oxide semiconductor. The p-type oxide semiconductor normally contains metal oxide as a major component. The metal oxide preferably contains d-block metal in the periodic table or metal in group 13 in the periodic table, and more preferably contains metal in group 9 or metal in group 13 in the periodic table. The expression of “the major component” means that the metal oxide is contained by preferably 50% or more, more preferably 70% or more, and further preferably 90% or more and may be 100% with respect to all components in the p-type oxide semiconductor at atomic ratio. In the present disclosure, it is preferred that the band gap of the p-type oxide semiconductor be 5.0 eV or more. In the present disclosure, the p-type oxide semiconductor may be monocrystal or may be polycrystal and the like.

In the present disclosure, it is preferred that the p-type oxide semiconductor also contain crystal or mixed crystal of metal oxide containing gallium. In this case, the p-type oxide semiconductor normally contains a p-type dopant. The p-type dopant is not particularly limited, but examples thereof include elements and the like of Mg, Zn, Ca, H, Li, Na, L, Rb, Cs, Fr, Be, Sr, Ba, Ra, Mn, Fe, Co, Ni, Pd, Cu, Ag, Au, Cd, Hg, Tl, Pb, N, P, and the like and two or more types thereof. Regarding the concentration of the dopant, the carrier concentration is normally lower than that of the deep p layer but may be about 1×10¹⁶/cm³ to 1×10²²/cm³ when the carrier concentration is lower than that of the deep p layer. In the present disclosure, it is preferred that the concentration of the dopant be a low concentration of about 1×10¹⁸/cm³ or less, for example.

The expression of “the periodic table” means the periodic table defined by International Union of Pure and Applied Chemistry (IUPAC). The expression of “the d-block” means elements having electrons that satisfy 3d, 4d, 5d, and 6d orbitals. Examples of the d-block metal include metal and the like of scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), lutetium (Lu), hafnium (Hf), tantalum (Ta), tungsten (W), rhenium (Re), osmium (Os), iridium (Ir), platinum (Pt), gold (Au), mercury (Hg), lawrencium (Lr), rutherfordium (Rf), dubnium (Db), seaborgium (Sg), bohrium (Bh), hassium (Hs), meitnerium (Mt), darmstadtium (Ds), roentgenium (Rg), copemicium (Cn) and two or more types thereof.

The deep p layer is not particularly limited as long as the deep p layer is a p-type semiconductor layer formed by a crystalline oxide semiconductor and having a higher carrier concentration than the channel layer. In the present disclosure, it is preferred that the breakdown field strength of the crystalline oxide semiconductor be 5 MV/cm or more because it becomes possible to exhibit the semiconductor property in a better manner. The crystalline oxide semiconductor preferably contains metal oxide containing d-block metal in the periodic table or metal in group 13 in the periodic table as a major component, and more preferably contains metal oxide containing metal in group 9 or metal in group 13 in the periodic table as a major component. The expression of “the major component” means that the metal oxide is contained by preferably 50% or more, more preferably 70% or more, and further preferably 90% or more and may be 100% with respect to all components in the crystalline oxide semiconductor at atomic ratio. In the present disclosure, the crystalline oxide semiconductor is preferred to have a corundum structure or a β-gallia structure and is also preferred to contain gallium oxide or mixed crystal thereof as a major component. The deep p layer normally contains a p-type dopant. The p-type dopant is not particularly limited, but examples thereof include elements and the like of Mg, Zn, Ca, H, Li, Na, L, Rb, Cs, Fr, Be, Sr, Ba, Ra, Mn, Fe, Co, Ni, Pd, Cu, Ag, Au, Cd, Hg, Tl, Pb, N, P, and the like and two or more types thereof. Regarding the concentration of the dopant, the carrier concentration is normally higher than that of the channel layer but may be about 1×10¹⁶/cm³ to 1×10²²/cm³ when the carrier concentration is higher than that of the channel layer. The carrier concentration of the deep p layer is preferably 1×10¹⁷/cm³ or more and is more preferably 1×10¹⁸/cm³ or more.

The semiconductor layer is not particularly limited as long as the semiconductor layer is formed by a semiconductor but is preferably an n-type semiconductor layer (including an n+-type semiconductor layer or an n--type semiconductor layer). In the present disclosure, it is preferred that the semiconductor layer be a crystalline oxide semiconductor layer. In the present disclosure, it is preferred that the breakdown field strength of the semiconductor layer be 5 MV/cm or more because it becomes possible to exhibit the semiconductor property in a better manner. In the present disclosure, the semiconductor layer is preferred to have a corundum structure or a β-gallia structure and is also preferred to contain gallium oxide or mixed crystal thereof. The thickness of the semiconductor layer is not particularly limited unless it interferes with the present disclosure. In the present disclosure, the thickness of the semiconductor layer is preferably 50 µm or less, more preferably 30 µm or less, and most preferably 10 µm or less. It is also preferred that the thickness of the deep p layer be set to half or more of the thickness of the semiconductor layer (for example, the n--type semiconductor layer). By setting the preferred thickness as above, it becomes possible to perform electric field relaxation of the crystalline oxide semiconductor in a more effective manner and exhibit the semiconductor property (including downsizing) in a better manner.

The crystalline oxide semiconductor layer normally includes an oxide semiconductor as a major component. The oxide semiconductor preferably contains gallium and more preferably is gallium oxide and mixed crystal thereof. The crystal structure and the like of the crystalline oxide semiconductor layer are not particularly limited. Examples of the crystal structure of the crystalline oxide semiconductor layer include a corundum structure, a β-gallia structure, a hexagonal crystal structure (for example, an ε-type structure), and the like. In the present disclosure, the crystalline oxide semiconductor layer preferably has a corundum structure or a β-gallia structure and more preferably has a corundum structure. The oxide semiconductor is not particularly limited, but preferably contains at least one type or two or more types of metal in period 3 to period 6 in the periodic table and more preferably contains at least one selected from gallium, indium, rhodium, iridium, and aluminum. It is preferred that the n-type oxide semiconductor contain at least gallium. The p-type oxide semiconductor preferably contains at least one selected from iridium and rhodium and more preferably contains iridium. Examples of the oxide semiconductor containing gallium include α-Ga₂O₃ or mixed crystal and the like. Examples of the oxide semiconductor containing iridium include α-Ir₂O₃ or mixed crystal thereof (for example, mixed crystal of iridium oxide and gallium oxide). In the crystalline oxide semiconductor layer including the preferred oxide semiconductor as above as a major component, the crystalline property and the heat release property may become better and the semiconductor property may become even better. The expression of “the major component” means that the oxide semiconductor is included by 50% or more, preferably 70% or more, and more preferably 90% or more at composition ratio in the crystalline semiconductor layer. For example, when the oxide semiconductor is α-Ga₂O₃, α-Ga₂O₃ only needs to be contained at a ratio at which the atomic ratio of gallium in the metal elements of the crystalline oxide semiconductor layer is 0.5 or more. In the present disclosure, the atomic ratio of gallium in the metal elements of the crystalline oxide semiconductor layer is preferably 0.7 or more and more preferably 0.8 or more. The oxide semiconductor may be a monocrystal or a polycrystal. The oxide semiconductor is normally in a film form but is not particularly limited unless it interferes with the present disclosure and may be in a plate form, a sheet form, a layer form, or a laminated body including a plurality of layers.

The oxide semiconductor may contain a dopant. The dopant is not particularly limited unless it interferes with the present disclosure. The dopant may be an n-type dopant or may be a p-type dopant. Examples of the n-type dopant include tin, germanium, silicon, titanium, zirconium, vanadium, niobium, or the like. Examples of the p-type dopant include magnesium, calcium, or the like. The concentration of the dopant may be set, as appropriate, and may specifically be about 1×10¹⁶/cm³ to 1×10²²/cm³, for example, or the concentration of the dopant may be a low concentration of about 1×10¹⁷/cm³ or less, for example. According to the present disclosure, the dopant may be contained by a high concentration of about 1×10²⁰/cm³ or more.

In the present disclosure, it is preferred that at least a part of a heat release portion be provided in a depth position of the buried lower end portion of the deep p layer in the semiconductor layer (hereinafter also referred to as a “crystalline oxide semiconductor layer”).

“The heat release portion” is not particularly limited as long as the heat release portion is capable of releasing heat in the crystalline oxide semiconductor layer and may be in a layer form, may be one part, or may be formed by parts provided in a row in a certain direction. A heat release portion or a heat release layer formed by a heat release member, a cooling portion having a cooling function, and the like, for example, are included in the heat release portion. The heat release member preferably has a thermal conductivity rate higher than that of the crystalline oxide semiconductor layer, more preferably has a thermal conductivity rate of 30 W/m·K or more, and most preferably has a thermal conductivity rate of 100 W/m·K or more. In the present disclosure, it is also preferred that the heat release member contain a conductive material. The conductive material is not particularly limited, but preferably has a higher electrical conductivity than the crystalline oxide semiconductor layer. Examples of such preferred conductive material include a p-type semiconductor and the like. The p-type semiconductor is not particularly limited. However, in the present disclosure, the p-type semiconductor is preferably a p-type crystalline oxide semiconductor, more preferably has a concentration gradient in the carrier concentration, and most preferably has a carrier concentration that becomes higher toward the depth direction. It becomes possible to exhibit a better semiconductor property by using such preferred heat release member.

In the present disclosure, it is preferred that the heat release portion be provided in the vicinity of the buried lower end portion of the gate electrode and/or a position deeper than the buried lower end portion. The number of the heat release portions may be two or more. When the number of the heat release portions is two or more, it is preferred that each of the heat release portions be systematically disposed with respect to the gate electrode. In the present disclosure, it is preferred that the heat release portion be disposed in parallel with the gate electrode in planar view, and it is also preferred that the heat release portion be thermally connected to the deep p layer. The heat release portion may be buried in the crystalline oxide semiconductor layer. By the configuration as above, it becomes possible to specifically dissolve local heat concentration in the crystalline oxide semiconductor layer.

It is possible to obtain the p-type oxide semiconductor, the crystalline oxide semiconductor, and the oxide semiconductor (hereinafter also collectively referred to as “the crystalline oxide semiconductor”) by causing epitaxial crystal growth by mist CVD or mist epitaxy, for example.

### <Crystal Substrate>

The crystal substrate is not particularly limited unless it interferes with the present disclosure and may be a well-known substrate. The crystal substrate may be an insulator substrate, a conductive substrate, or a semiconductor substrate. The crystal substrate may be a monocrystalline substrate or a polycrystalline substrate. Examples of the crystal substrate include a substrate containing a crystal substance having a corundum structure as the major component. The expression of “major component” means that the crystal substance is contained by 50% or more, preferably 70% or more, and more preferably 90% or more at composition ratio in the substrate. Examples of the crystal substrate having a corundum structure include a sapphire substrate, and an α-type gallium oxide substrate.

In the present disclosure, it is preferred that the crystal substrate be a sapphire substrate. Examples of the sapphire substrate include a c-plane sapphire substrate, an m-plane sapphire substrate, an α-plane sapphire substrate, and an r-plane sapphire substrate. The sapphire substrate may have an off-angle. The off-angle is not particularly limited and is 0.01 degrees or more, for example, but is preferably 0.2 degrees or more and more preferably from 0.2 degrees to 12 degrees. It is preferred that the sapphire substrate has a crystal-growth-plane that is an α-plane, an m-plane, or an r-plane, and it is also preferred that the sapphire substrate is a c-plane sapphire substrate having an off-angle of 0.2 degrees or more.

The thickness of the crystal substrate is not particularly limited but is normally from 10 µm to 20 mm and is more preferably from 10 µm to 1000 µm.

The crystal substrate may have a shape at least including a first crystal axis and a second crystal axis or may have grooves corresponding to the first crystal axis and the second crystal axis formed therein.

Examples of a suitable shape of the crystal substrate include a circular shape, a polygonal shape such as a triangular shape, a quadrilateral shape (for example, a rectangular shape or a trapezoid shape), a pentagonal shape, or a hexagonal shape, a fan shape, and the like.

In the present disclosure, other layers such as a buffer layer and a stress alleviation layer may be provided on the crystal substrate. Examples of the buffer layer include a layer formed by metal oxide having the same crystal structure as the crystal structure of the crystal substrate or the crystalline oxide semiconductor. Examples of the stress alleviation layer include an ELO mask layer.

Methods for epitaxial crystal growth is not particularly limited unless it interferes with the present disclosure and may be well-known methods. Examples of the epitaxial crystal growth methods include CVD, MOCVD, MOVPE, mist CVD, mist epitaxy, MBE, HVPE, pulsed growth, or ALD. In the present disclosure, it is preferred that the epitaxial crystal growth be performed by mist CVD or mist epitaxy.

The mist CVD or the mist epitaxy is performed by atomizing a raw material solution containing metal (atomization process), causing droplets to float and carrying the obtained atomized droplets to the vicinity of the crystal substrate by carrier gas (carrying process), and then causing thermal reaction of the atomized droplets (film formation process).

### (Raw Material Solution)

The raw material solution is not particularly limited as long as metal is contained as the raw material for film formation and atomization is possible and may contain an inorganic material or an organic material. The metal may be elemental metal or a metal compound and is not particularly limited unless it interferes with the present disclosure. Examples the metal include one type or two or more types of metal and the like selected from gallium (Ga), iridium (Ir), indium (In), rhodium (Rh), aluminum (Al), gold (Au), silver (Ag), platinum (Pt), copper (Cu), iron (Fe), manganese (Mn), nickel (Ni), palladium (Pd), cobalt (Co), ruthenium (Ru), chromium (Cr), molybdenum (Mo), tungsten (W), tantalum (Ta), zinc (Zn), lead (Pb), rhenium (Re), titanium (Ti), tin (Sn), magnesium (Mg), calcium (Ca), and zirconium (Zr). However, in the present disclosure, the metal preferably includes at least one type or two or more types of metal in period 3 to period 6 in the periodic table, more preferably includes at least one selected from gallium, indium, rhodium, iridium, and aluminum, and most preferably includes at least gallium. In the present disclosure, it is also preferred that the metal include gallium, indium, and/or aluminum. By using the preferred metal as above, it becomes possible to perform film formation of the crystalline oxide semiconductor usable in the semiconductor device and the like in a more suitable manner.

In the present disclosure, as the raw material solution, a raw material solution obtained by causing the metal to be dissolved or dispersed in an organic solvent or water in a form of a complex or salt is suitably usable. Examples of the form of a complex include an acetylacetonato complex, a carbonyl complex, an ammine complex, and a hydride complex. Examples of the form of salt include organometallic salt (for example, metal acetate salt, metal oxalate salt, and metal citrate salt), metal sulfate salt, metal nitrate salt, metal phosphate salt, and metal halide salt (for example, metal chloride salt, metal bromide salt, and metal iodine salt).

The solvent of the raw material solution is not particularly limited unless it interferes with the present disclosure and may be an inorganic solvent such as water, an organic solvent such as alcohol, or a mixed solvent of an inorganic solvent and an organic solvent. In the present disclosure, it is preferred that the solvent contain water.

In the raw material solution, additives such as hydrohalic acid and oxidant may be mixed. Examples of the hydrohalic acid include hydrobromic acid, hydrochloric acid, and hydriodic acid. Examples of the oxidant include peroxide such as hydrogen peroxide (H₂O₂), sodium peroxide (Na₂O₂), barium peroxide (BaO₂), benzoyl peroxide (C₆H₅CO)₂O₂, and organic peroxide such as hypochlorous acid (HClO), perchloric acid, nitric acid, ozone water, peracetic acid, and nitrobenzene.

A dopant may be contained in the raw material solution. The dopant is not particularly limited unless it interferes with the present disclosure. Examples of the dopant include an n-type dopant of tin, germanium, silicon, titanium, zirconium, vanadium, niobium, or the like, a p-type dopant of magnesium, calcium, or the like, and the like. The concentration of the dopant may be from about 1×10¹⁶/cm³ to about 1×10²²/cm³, for example, or concentration of the dopant may be a low concentration of about 1×10¹⁷/cm³ or less, for example. According to the present disclosure, the dopant may be contained at a high concentration of about 1×10²⁰/cm³ or more.

### (Atomization Process)

The atomization process adjusts a raw material solution containing metal, atomizes the raw material solution, causes droplets to float, and generates atomization droplets. The blending ratio of the metal is not particularly limited but is preferably from 0.0001 mol/L to 20 mol/L with respect to the entire raw material solution. The atomization methods is not particularly limited as long as atomization of the raw material solution is possible, and the atomization methods may be well-known atomization methods, but is preferably atomization methods using ultrasonic vibration in the present disclosure. It is more preferred that the mist used in the present disclosure float on air and be mist that is not sprayed like a spray, for example, but has zero initial velocity, floats on air, and is able to be carried as gas. The droplet size of the mist is not particularly limited but may be a droplet of about several millimeters, but is preferably 50 µm or less and more preferably from 1 µm to 10 µm.

### (Carrying Process)

In the carrying process, the atomization droplets are carried to the crystal substrate by the carrier gas. The type of the carrier gas is not particularly limited unless it interferes with the present disclosure, and suitable examples thereof include oxygen, ozone, inert gas (for example, nitrogen and argon), or reducing gas (hydrogen gas, forming gas, and the like). The type of the carrier gas may be one type but also may be two or more types, and diluent gas (for example, ten-fold dilution gas) obtained by changing the carrier gas concentration, for example, may further be used as second carrier gas. The supplying place of the carrier gas does not necessarily need to be one place and may be two or more places. The flow rate of the carrier gas is not particularly limited but is preferably 1 LPM or less and more preferably from 0.1 LPM to 1 LPM.

### (Film Formation Process)

In the film formation process, a film is formed on the crystal substrate by causing the atomization droplets to react. The reaction is not particularly limited as long as a film is formed from the atomization droplets in the reaction but is preferably thermal reaction in the present disclosure. The thermal reaction only needs to be a reaction in which the atomization droplets react by heat, and the reaction conditions and the like are not particularly limited unless it interferes with the present disclosure. In the present process, the thermal reaction is normally performed at a temperature equal to or more than an evaporation temperature of the solvent of the raw material solution but is preferably a temperature that is not too high and is more preferably 650° C. or less. The thermal reaction may be performed under any atmosphere out of vacuum, non-oxygen atmosphere, reducing gas atmosphere, and oxygen atmosphere and may be performed under any condition out of atmospheric pressure, pressurization, and depressurization unless it interferes with the present disclosure. However, in the present disclosure, it is preferred that the thermal reaction be performed under atmospheric pressure because it becomes easier to calculate the evaporation temperature and it becomes possible to simplify equipment and the like, for example. The film thickness is settable by adjusting the amount of time of the film formation.

The semiconductor device of the present disclosure normally includes a source electrode (emitter electrode) and a drain electrode (collector electrode). Well-known electrode materials may be used for the source electrode (emitter electrode) and the drain electrode (collector electrode), and the source electrode (emitter electrode) and the drain electrode (collector electrode) are not particularly limited unless it interferes with the present disclosure, but suitable examples thereof include a material including metal in group 4 or group 11 in the periodic table and the like. Suitable metal in group 4 or group 11 in the periodic table used in the source electrode (emitter electrode) and the drain electrode (collector electrode) may be similar to metal included in the gate electrode. The source electrode (emitter electrode) and the drain electrode (collector electrode) may be a metal layer that is a single layer or may include two or more metal layers. Formation means for the source electrode (emitter electrode) and the drain electrode (collector electrode) is not particularly limited, and examples thereof include well-known means such as vacuum deposition, spattering, and the like. Metal configuring the source electrode and the drain electrode may be alloy.

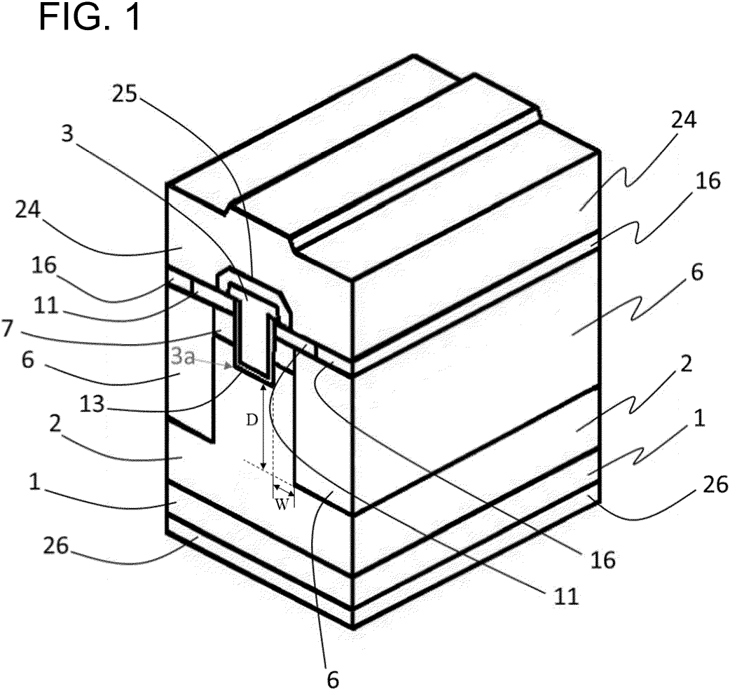

A suitable semiconductor device in the present disclosure is illustrated in FIG. 1. The semiconductor device in FIG. 1 is a metal-oxide-semiconductor field-effect transistor (MOSFET) and includes an n+-type semiconductor layer 1, an n--type semiconductor layer 2, a p+-type semiconductor layer (deep p layer) 6, a p--type semiconductor layer (channel layer) 7, an n+-type semiconductor layer 11, a gate insulating film 13, a gate electrode 3, a p+-type semiconductor layer 16, a source electrode 24, an interlayer insulating film 25, and a drain electrode 26. The p+-type semiconductor layer (deep p layer) 6 has at least a part thereof buried in the n--type semiconductor layer 2 to a position deeper than a buried lower end portion 3a of the gate electrode 3. In the ON-state of the semiconductor device in FIG. 1, when voltage is applied across the source electrode 24 and the drain electrode 26 and voltage positive with respect to the source electrode 24 is applied to the gate electrode 3, a channel is formed in an interface between the p--type semiconductor layer 7 and the gate insulating film 13, and turning ON is performed. Regarding the OFF state, the voltage across the gate electrode 3 is caused to be 0 V. As a result, a channel is not formed, and turning OFF is performed. In the semiconductor device in FIG. 1, the p+-type semiconductor layer 6 is buried in the n--type semiconductor layer 2 at a place deeper than the gate electrode 3. By the configuration as above, it becomes possible to relax the electric field in the vicinity of a lower portion of the gate electrode 3 and cause the electric field distribution in the gate insulating film 13 and the n--type semiconductor layer 2 to be better. In the present disclosure, the carrier density of the n--type semiconductor layer 2 is preferably 1.4×10¹⁷/cm³ or less when the voltage resistance is 600 V and is preferably 6.9×10¹⁶/cm³ or less when the voltage resistance is 1200 V. The depth (D in FIG. 1) of the deep p layer 6 is preferably 1.0 µm or more. Further, the depth (D in FIG. 1) of the deep p layer 6 is preferably 1.5 µm or more because it becomes possible to relax the electric field more. The relationship between the depth D of the deep p layer 6 and the drift layer concentration is preferably y≥2.67×10-17x-0.83 (y represents the depth of the deep p layer 6, and x represents the drift layer (n--type semiconductor layer 2) concentration, respectively) when the voltage resistance is 600 V and is preferably y≥1.89×10-17x+0.39 (y represents the depth of the deep p layer 6, and x represents the drift layer (n--type semiconductor layer 2) concentration, respectively) when the voltage resistance is 1200 V. It is preferred that an interval (W in FIG. 1) between the deep p layer 6 and a gate trench be 0.5 µm or less.

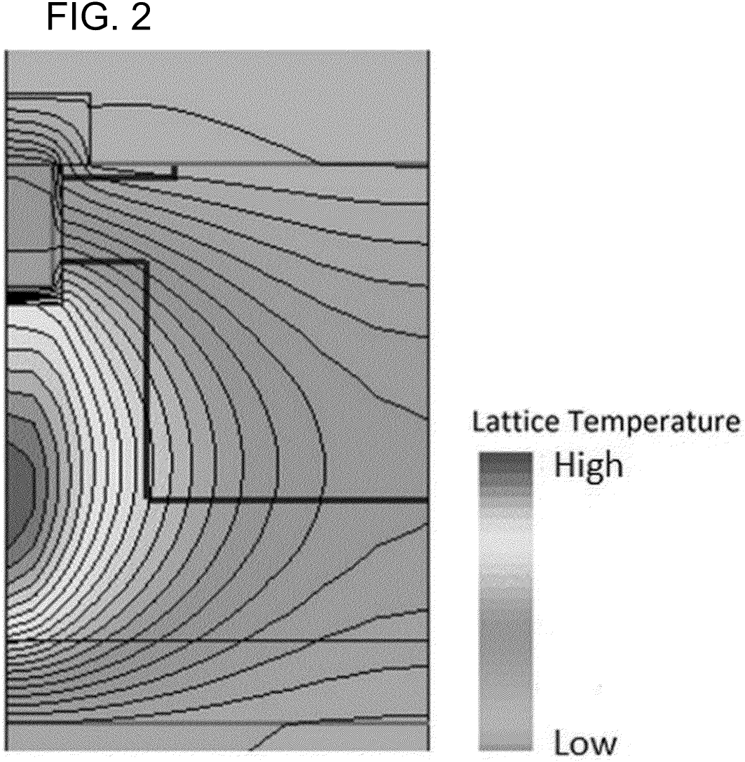

As a result of simulating the electric field of the semiconductor device in FIG. 1, it has been found that the electric field is satisfactory. The heat distribution in the semiconductor device in FIG. 1 has also been simulated, but a thermal concentration has been found below the gate electrode 3 as illustrated in FIG. 2. Therefore, in the present disclosure, it is preferred that the heat release portion be provided for the purpose of alleviating such thermal concentration.

Formation means for each layer in the semiconductor device in FIG. 1 is not particularly limited unless it interferes with the present disclosure and may be well-known means. Examples include means for directly performing patterning with use of a printing technique or means for performing patterning by photolithography after forming a film by vacuum deposition, CVD, spattering, various coating techniques, and the like, but mist CVD is preferred in the present disclosure.

A film formation apparatus in mist CVD is described below.

A film formation apparatus 601 in FIG. 7 includes a carrier gas apparatus 622a that supplies carrier gas, a flow rate regulation valve 623a for regulating the flow rate of the carrier gas sent out from the carrier gas apparatus 622a, a carrier gas (diluted) apparatus 622b that supplies carrier gas (diluted), a flow rate regulation valve 623b for regulating the flow rate of the carrier gas (diluted) sent out from the carrier gas (diluted) apparatus 622b, a mist generation source 624 in which a raw material solution 624a is accommodated, a container 625 in which water 625a is placed, an ultrasonic transducer 626 mounted on a bottom plane of the container 625, a film formation chamber 630, a supply pipe 627 made of quartz that forms connection from the mist generation source 624 to the film formation chamber 630, and a hotplate (heater) 628 installed in the film formation chamber 630. A substrate 603 is installed on the hotplate 628.

As illustrated in FIG. 7, the raw material solution 624a is accommodated in the mist generation source 624. Next, the substrate 603 is installed on the hotplate 628, the hotplate 628 is actuated, and the temperature in the film formation chamber 630 is raised. Next, the carrier gas is supplied into the film formation chamber 630 from the carrier gas apparatus 622a and the carrier gas (diluted) apparatus 622b that are carrier gas sources by opening the flow rate regulation valves 623 (623a, 623b), and the atmosphere in the film formation chamber 630 is sufficiently replaced with the carrier gas. Then, the flow rate of the carrier gas and the flow rate of the carrier gas (diluted) are regulated. Next, the ultrasonic transducer 626 is vibrated, and the vibration is propagated to the raw material solution 624a through the water 625a. As a result, the raw material solution 624a is atomized and atomization droplets 624b are generated. The atomization droplets 624b are introduced into the film formation chamber 630 by the carrier gas and are carried to the substrate 603. Then, the atomization droplets 624b thermally react in the film formation chamber 630 under atmospheric pressure, and a film is formed on the substrate 603.

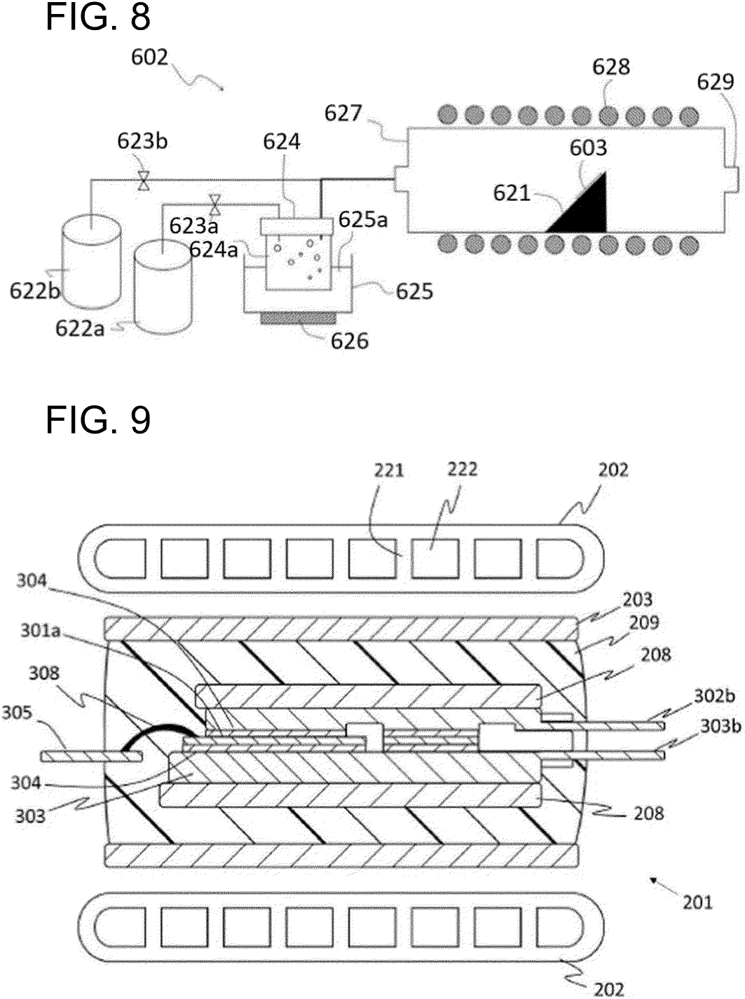

It is also preferred that a mist CVD apparatus (film formation apparatus) 602 illustrated in FIG. 8 be used. The mist CVD apparatus 602 in FIG. 8 includes a susceptor 621 on which the substrate 603 is placed, the carrier gas supplying apparatus 622a that supplies carrier gas, the flow rate regulation valve 623a for regulating the flow rate of the carrier gas sent out from the carrier gas supplying apparatus 622a, the carrier gas (diluted) supplying apparatus 622b that supplies carrier gas (diluted), the flow rate regulation valve 623b for regulating the flow rate of the carrier gas sent out from the carrier gas (diluted) supplying apparatus 622b, the mist generation source 624 in which the raw material solution 624a is accommodated, the container 625 in which the water 625a is placed, the ultrasonic transducer 626 mounted on the bottom plane of the container 625, the supply pipe 627 formed by a quartz pipe with an inner diameter of 40 mm, the heater 628 installed on a peripheral portion of the supply pipe 627, and an exhaust port 629 that discharges exhaust gas, droplets, and mist after the thermal reaction. The susceptor 621 is made of quartz, and a plane on which the substrate 603 is placed is inclined from the horizontal plane. By producing both of the supply pipe 627 and the susceptor 621 serving as the film formation chamber by quartz, a case where impurities derived from the apparatus are mixed into the film formed on the substrate 603 is suppressed. It is possible to treat the mist CVD apparatus 602 in a manner similar to the film formation apparatus 601.

With use of the suitable film formation apparatus, it becomes possible to form the crystalline oxide semiconductor on the crystal growth plane of the crystal substrate in an easier manner. The crystalline oxide semiconductor layer is normally formed by epitaxial crystal growth. It is possible to produce the semiconductor device from the crystalline oxide semiconductor with use of well-known means.

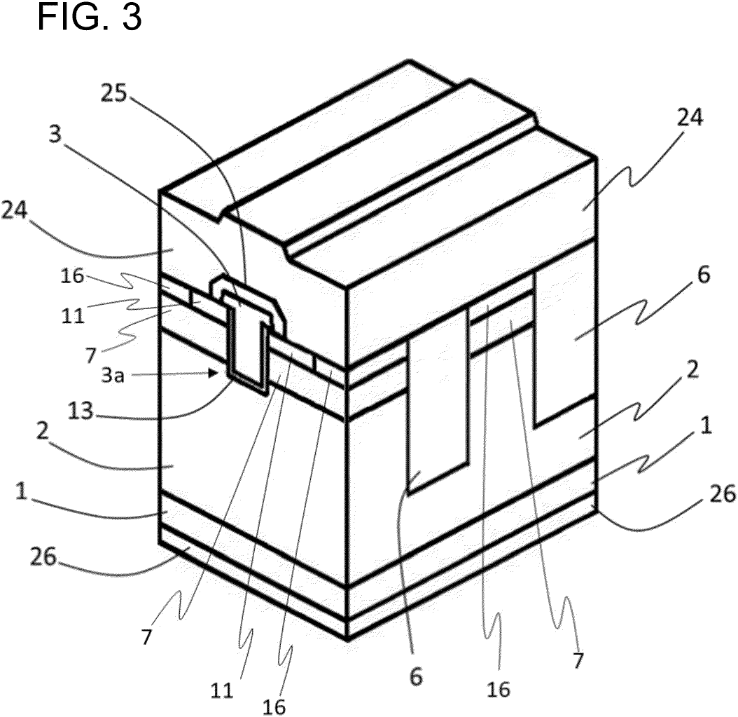

Another suitable aspect as the semiconductor device of the present disclosure is illustrated in FIG. 3. The semiconductor device in FIG. 3 is a metal-oxide-semiconductor field-effect transistor (MOSFET) and includes the n+-type semiconductor layer 1, the n--type semiconductor layer 2, the p+-type semiconductor layer (deep p layer) 6, the gate insulating film 13, the gate electrode 3, the source electrode 24, the interlayer insulating film 25, and the drain electrode 26. The semiconductor device in FIG. 3 also includes the p--type semiconductor layer (he channel layer) 7, the n+-type semiconductor layer 11, and the p+-type semiconductor layer 16. The p+-type semiconductor layer (deep p layer) 6 has at least a part thereof buried in the semiconductor layer (for example, the n--type semiconductor layer 2) to a position deeper than the buried lower end portion 3a of the gate electrode 3. The semiconductor device in FIG. 3 is different from the semiconductor device in FIG. 1 in that the p+-type semiconductor layer 6 is provided to be orthogonal to the gate electrode 3. The semiconductor device as above is also suitable and may also exhibit an excellent electric field relaxation effect.

In the semiconductor device of the present disclosure, the thickness of the semiconductor layer is preferably 50 µm or less, more preferably 30 µm or less, and most preferably 10 µm or less so as to perform electric field relaxation of the crystalline oxide semiconductor in a more effective manner and exhibit the semiconductor property (including downsizing) in a better manner. It is preferred that the thickness of the deep p layer be set to half or more of the thickness of the semiconductor layer (for example, the n--type semiconductor layer 2).

In the present disclosure, it is preferred that the semiconductor device include: a gate insulating film and a gate electrode each having at least a part buried in an n-type semiconductor layer; a first deep p layer and a second deep p layer each having at least a part buried in the semiconductor layer to a same depth as a buried lower end portion of the gate electrode or a position deeper than the buried lower end portion; and a channel layer. In the semiconductor device, it is preferred that the gate insulating film and the gate electrode be provided on an upper side between the first deep p layer and the second deep p layer, both of the deep p layers be formed by a crystalline oxide semiconductor, and a carrier concentration of the deep p layer be higher than a carrier concentration of the channel layer. According to such semiconductor device, it becomes possible to exhibit a better electric field relaxation effect and exhibit the semiconductor property of the crystalline oxide semiconductor in a more sufficient manner.

In the present disclosure, it is preferred that the semiconductor device further include a heat release portion. The heat release portion is not particularly limited as long as heat release portion is capable of releasing heat and may be in a layer form, may be one part, or may be formed by parts provided in a row in a linear manner. A heat release portion or a heat release layer formed by a heat release member, a cooling portion having a cooling function, and the like, for example, are included in the heat release portion. The heat release member is not particularly limited as long as the heat release member has a higher thermal conductivity than the crystalline semiconductor layer. In the present disclosure, it is preferred that the heat release member be a conductive member. It is preferred that the conductive member be a p-type crystalline oxide semiconductor. In the present disclosure, it is more preferred that the heat release portion be included in the vicinity of the gate electrode or a position deeper than the gate electrode.

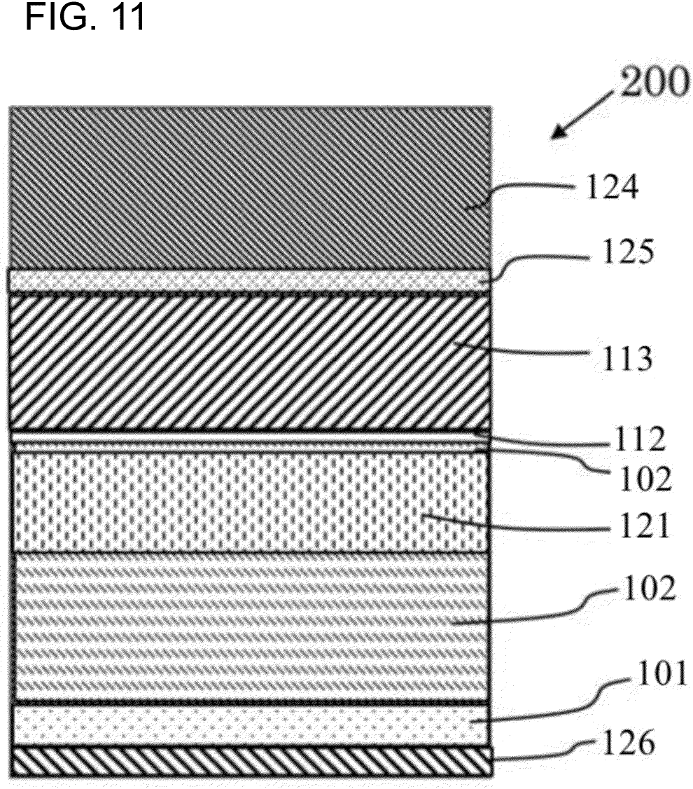

FIG. 10 illustrates a schematic view of the semiconductor device having a heat release structure. The semiconductor device in FIG. 10 is different from FIG. 1 in terms of having a heat release portion 121. The semiconductor device 200 has a laminated body 150 including a crystalline oxide semiconductor layer 101, a gate electrode 113 having at least a part buried in the laminated body 150, and a heat release portion 121 having at least a part positioned deeper than a buried end portion 113b of the gate electrode 113. The heat release portion 121 is positioned below the buried end portion 113b of the gate electrode 113. The heat release portion 121 is buried on the inside of the second crystalline oxide semiconductor layer 102 (n--type semiconductor layer). The heat release portion 121 is in a position closer to the gate electrode 113 than a deep p layer 106 in an outer position in planar view. In other words, the heat release portion 121 at least partially overlaps with the gate electrode in planar view.

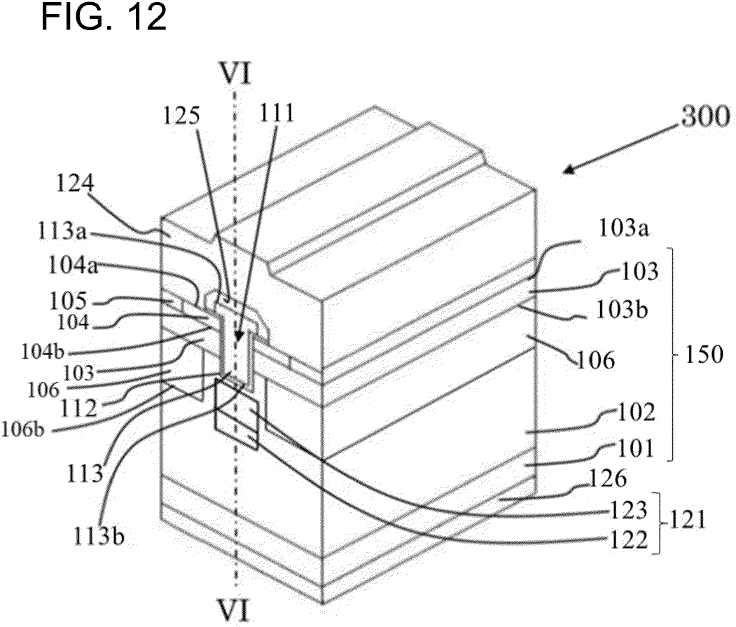

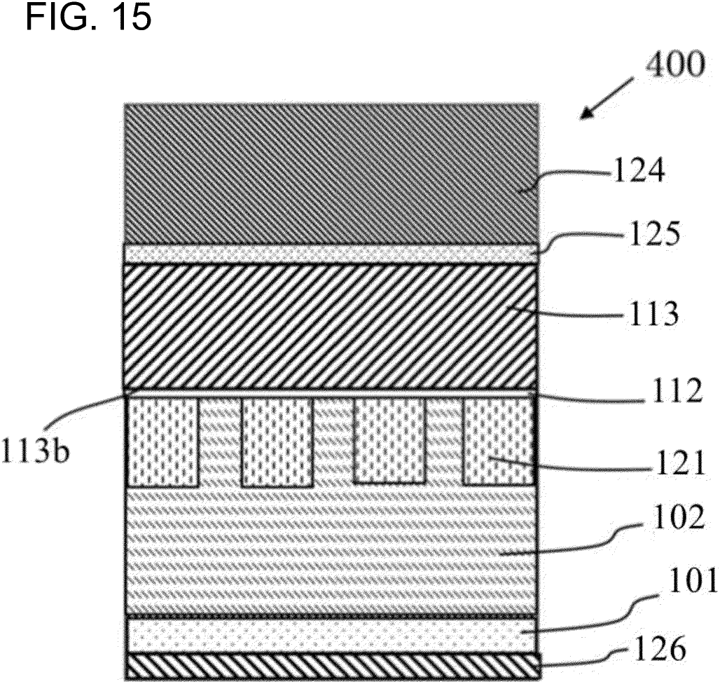

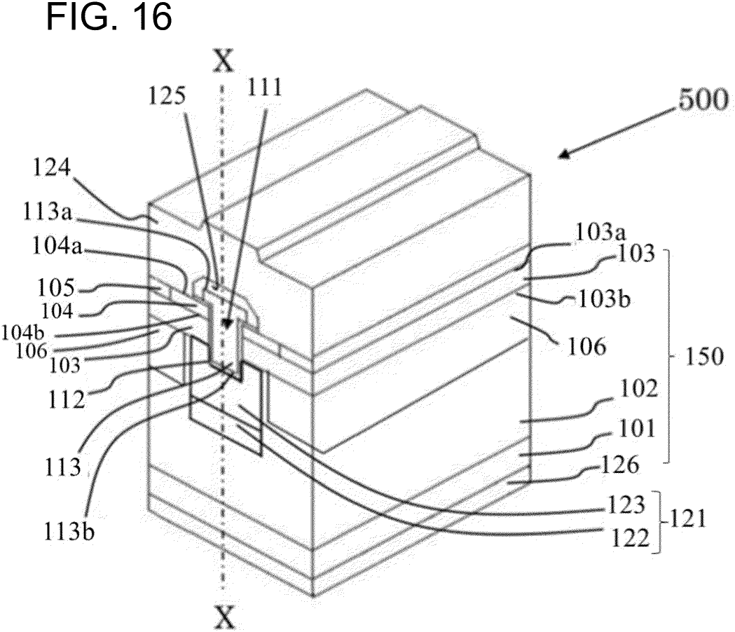

The semiconductor device 200 may further have a first semiconductor region 104 (source region) disposed on the third crystalline oxide semiconductor layer 103 (p-type semiconductor layer) and having a higher carrier density than the second crystalline oxide semiconductor layer 102 (n--type semiconductor layer), and a second semiconductor region 105 (contact region) disposed on the third crystalline oxide semiconductor layer 103 (p-type semiconductor layer) and having a higher carrier density than the third crystalline oxide semiconductor layer 103 (p-type semiconductor layer). The gate electrode 113 extends in a first direction (depth direction) that penetrates from a first plane 104a of the first semiconductor region 104 (source region) to a second plane 104b on the opposite side and further penetrates from a first plane 103a of the third crystalline oxide semiconductor layer 103 (p-type semiconductor layer) to a second plane 103b on the opposite side and a second direction having an angle with respect to the first direction. The second direction may be a diagonal direction or may be perpendicular to the first direction in accordance with the design of the semiconductor device. It becomes possible to diffuse the heat on the inside of the crystalline oxide semiconductor layer in a more efficient manner when the center of the heat release portion 121 is disposed in a position in which the first direction (depth direction) of the gate electrode and a virtual extended line of the buried lower end portion 106b of the deep p layer 106 intersect each other. As another example, the heat release portion 121 may have a contact plane with respect to the deep p layer 106. When the heat release portion 121 is thermally connected to the deep p layer 106, it becomes possible to release the heat trapped on the inside of the crystalline oxide semiconductor layer to the outside of the semiconductor device in a more efficient manner. In FIG. 10, the gate electrode is illustrated to be extended in the first direction and a direction perpendicular to the first direction (the longitudinal direction of the semiconductor device in FIG. 10). The buried end portion 113b of the gate electrode 113 extends in the second direction as a buried end plane, and the heat release portion 121 positioned below the buried end plane of the gate electrode 113 may also be disposed to extend in the second direction along the buried end plane of the gate electrode 113. As illustrated in the cross-sectional view of FIG. 11, the heat release portion 121 may be integrally provided, or a plurality of two or more of the heat release portions 121 may be adjacently provided or be disposed to be spaced apart from each other as illustrated in FIG. 15. FIG. 11 is a view schematically illustrating a cross-section of the semiconductor device in FIG. 10 including line IV-IV and taken along a plane parallel to the longitudinal direction of the semiconductor device 200. FIG. 15 is a view schematically illustrating a cross-section of the semiconductor device in FIG. 14 including line VIII-VIII and taken along a plane parallel to the longitudinal direction of the semiconductor device 400. When the semiconductor devices 200, 400 are metal-oxide-semiconductor field-effect transistors (MOSFETs), the crystalline oxide semiconductor layer 1 is an n-type semiconductor layer. When the semiconductor devices are insulated gate bipolar transistors (IGBTs), the crystalline oxide semiconductor layer 1 is a p+-type semiconductor layer.

The material of the heat release portion 121 may be a well-known material, but the thermal conductivity of the heat release portion 121 needs to be higher than the thermal conductivity of the crystalline oxide semiconductor layer of which heat release portion is buried. For example, when the major component of the first crystalline oxide semiconductor layer 102 is gallium oxide, the heat release portion 21 includes a material having a higher thermal conductivity than the gallium oxide. For example, the heat release portion 121 may include metal (for example, aluminum and copper), metal compound and/or metal oxide having a high thermal conductivity or may include a material having a high thermal conductivity such as silicide, polysilicon, and graphite. The heat release portion 21 may have conductivity.

The heat release portion 21 may include a second-conductivity-type (p-type) impurity. The concentration of the second-conductivity-type impurity may be different between a position around a first plane 121a of the heat release portion 121 closer to the gate electrode and a position around a second plane 21b on the side opposite from the first plane 121a. The heat release portion 121 may have a concentration that becomes higher toward the first direction (depth direction). It is preferred that a second plane 121b of the heat release portion 121 be in a position deeper than the second plane 106b of the deep p layer 106 in the outer position.

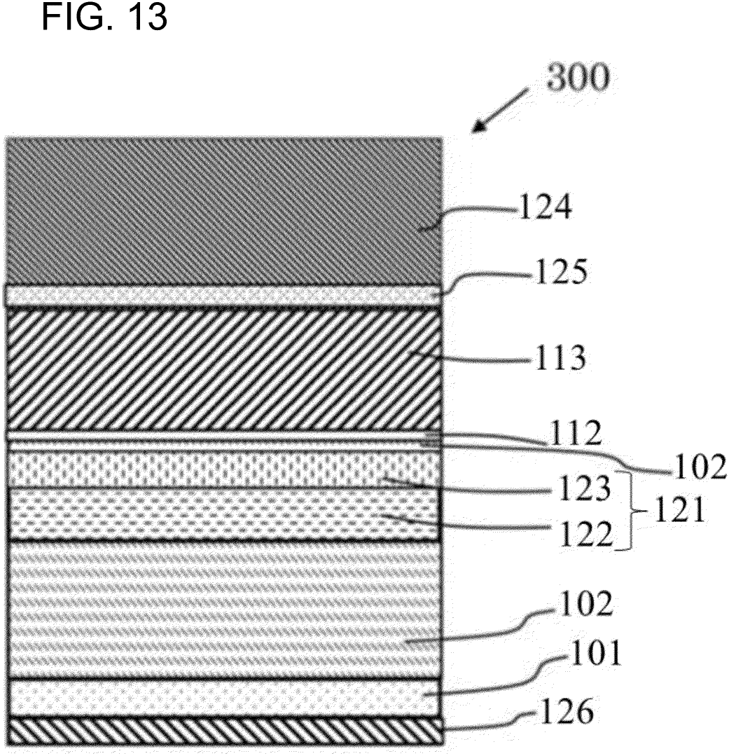

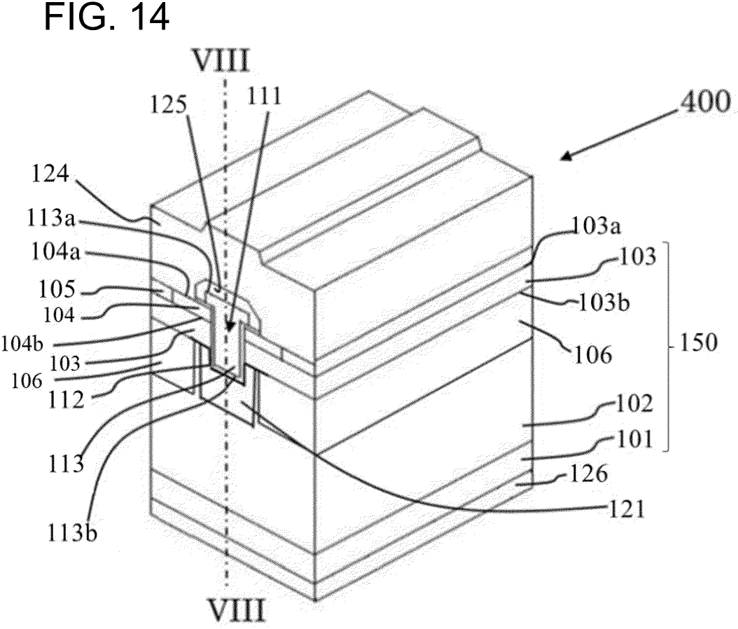

FIG. 12 illustrates another schematic view of a semiconductor device having a heat release structure. The semiconductor device in FIG. 12 is different from the semiconductor device in FIG. 10 in that the heat release portion 121 has a first concentration region 123 and a second concentration region 122. In the semiconductor device 300, the heat release portion 121 disposed below the buried end portion 113b of the gate electrode 113 may have the first concentration region 123 (p-), and the second concentration region 122 (p) of which concentration of the second-conductivity-type impurity is higher than that of the first concentration region 123. FIG. 13 is a view schematically illustrating a cross-section of the semiconductor device in FIG. 12 including line VI-VI and taken along a plane parallel to the longitudinal direction of the semiconductor device 300. As illustrated in the cross-sectional view in FIG. 13, the heat release portion 121 may be integrally provided. As illustrated in the cross-sectional view in FIG. 15, the plurality of two or more heat release portions 121 may be disposed to be adjacent to each other or spaced apart from each other along the buried end portion 113b of the gate electrode 113 (second direction). However, it becomes possible to efficiently diffuse heat on the inside of the oxide semiconductor layer (for example, the second crystalline oxide semiconductor layer 102)by disposing the heat release portion 121 on the inside of the laminated body 150 including the crystalline oxide semiconductor layer at a position deeper than the buried end portion 113b of the gate electrode 13 as shown in a simulation evaluation result in FIG. 2.

FIG. 14 illustrates another schematic view of a semiconductor device having a heat release structure. The semiconductor device 400 has the heat release portion 121 thermally connected to at least two planes including the buried end portion 113b of the gate electrode 113 via an insulating film 112. The heat release portion 121 has a depressed portion extending in the second direction on an upper plane, the depressed portion of the heat release portion 121 may configure a part of a trench 111, and a lower portion including the buried end portion 113b of the gate electrode 113 is connected to the heat release portion 121 via the insulating film 112. In the heat release portion 121, the width may differ between an upper plane and a bottom plane, and the width may become narrower from the upper plane toward the bottom plane. The second crystalline oxide semiconductor layer 102 may have a current diffusion region disposed between two or more of the second-conductivity-type deep p layers 106. FIG. 15 is a view schematically illustrating a cross-section of the semiconductor device in FIG. 14 including line VIII-VIII and taken along a plane parallel to the longitudinal direction of the semiconductor device 400.

In FIG. 14, an upper end portion 13a of the gate electrode 113 is not buried in the trench 111. However, in the present disclosure, it is preferred that the gate electrode 113 be buried in the trench 111. More specifically, for example, it is more preferred that an upper end portion 113a of the gate electrode 113 be buried in the trench 111.

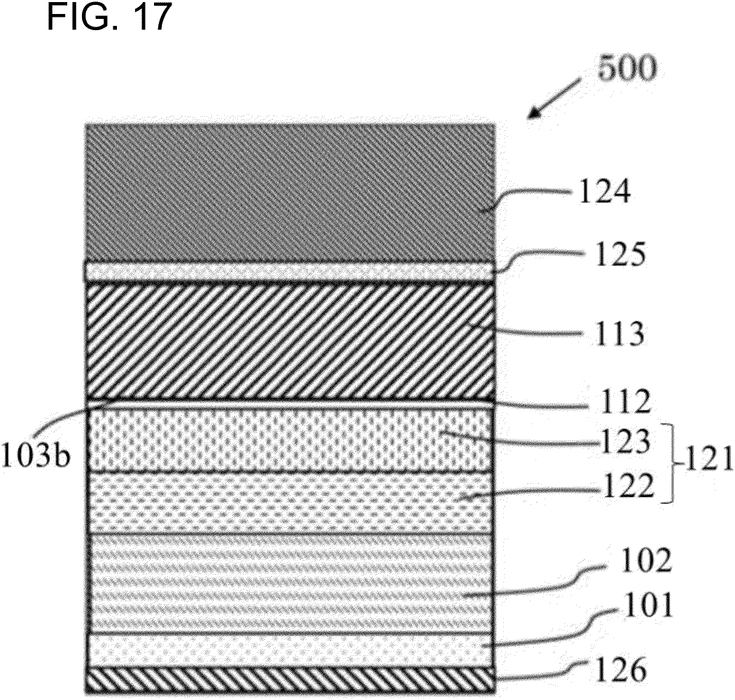

FIG. 16 illustrates another schematic view of a semiconductor device having a heat release structure. A semiconductor device 500 has the heat release portion 121 thermally connected to at least two planes including the buried end portion 113b of the gate electrode 113 via the insulating film 112. The heat release portion 121 has a depressed portion extending in the second direction on an upper plane, the depressed portion of the heat release portion 21 may configure a part of a trench 111, and a lower portion including the buried end portion 113b of the gate electrode 113 is connected to the heat release portion 121 via the insulating film 112. The heat release portion 121 may include a second-conductivity-type (p-type) impurity, and the concentration of the second-conductivity-type impurity may differ between the upper plane of the heat release portion 121 with a depressed portion and the bottom plane of the heat release portion 121. The heat release portion 121 may have a concentration that becomes higher toward the first direction (depth direction). FIG. 17 is a view schematically illustrating a cross-section of the semiconductor device in FIG. 16 including line X-X and taken along a plane parallel to the longitudinal direction of the semiconductor device 500. As illustrated in the cross-sectional view of FIG. 17, the heat release portion 121 may be integrally provided, or the plurality of two or more heat release portions 121 may be adjacently provided or be disposed to be spaced apart from each other as illustrated in FIG. 15. The first concentration region 123 of the heat release portion 21 is in a position closer to a trench side plane than the second concentration region 122. The first concentration region forms an inversion layer in a position close to the side plane of the trench when voltage is applied to the second electrode.

A high heat portion as that shown in FIG. 2 has not been generated as a result of examining the heat distribution around the gate electrode of each of the semiconductor devices illustrated in FIG. 10, FIG. 12, FIG. 14, and FIG. 16 when α-Ga₂O₃ is used in the crystalline oxide semiconductor layer and a p-type oxide semiconductor (α-Ir₂O₃ or α-Ga₂O₃ doped with Mg) is used in the heat release portion. From the above, it is understood that it becomes possible to prevent or suppress local increase in heat caused by electric field concentration due to the gate electrode having at least a part that is buried, and that the semiconductor property is excellent according to the present disclosure.

The semiconductor device is particularly suitable for use in a power device and is especially used as a normally-off-type semiconductor device in a suitable manner. In the present disclosure, it becomes possible to use the crystalline oxide semiconductor in the semiconductor device by peeling the crystalline oxide semiconductor from the crystal substrate with use of well-known means on request, for example, and suitably use the crystalline oxide semiconductor as a vertical device. The semiconductor device is suitably used for both of a horizontal element (horizontal device) in which the electrode is formed on one plane side of the semiconductor layer and a vertical element (vertical device) having an electrode on each of both front and rear plane sides of the semiconductor layer, but it is especially preferred to use the semiconductor device in a vertical device in the present disclosure. Suitable examples of the semiconductor device include a metal-semiconductor field-effect transistor (MESFET), a high electron mobility transistor (HEMT), a metal-oxide-semiconductor field-effect transistor (MOSFET), a static induction transistor (SIT), a junction field-effect transistor (JFET), an insulated gate bipolar transistor (IGBT), and the like. In the present disclosure, an insulated gate semiconductor device (for example, a MOSFET or an IGBT) or a semiconductor device (for example, an MESFET) having a Schottky gate is especially preferred, and a MOSFET or an IGBT is especially preferred more.

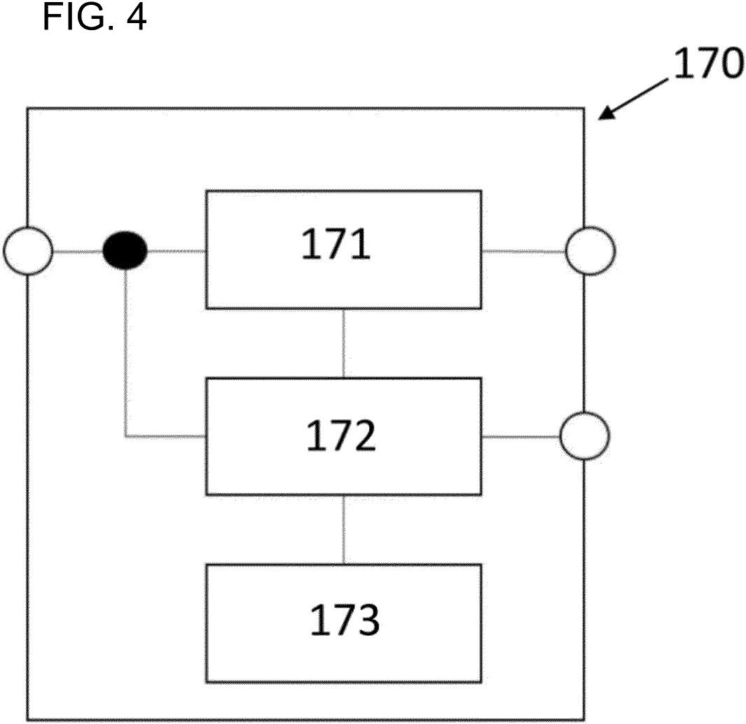

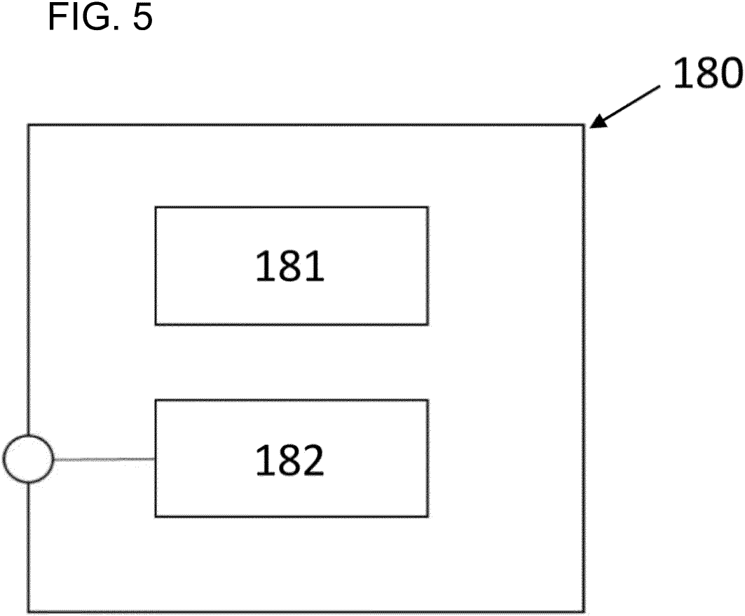

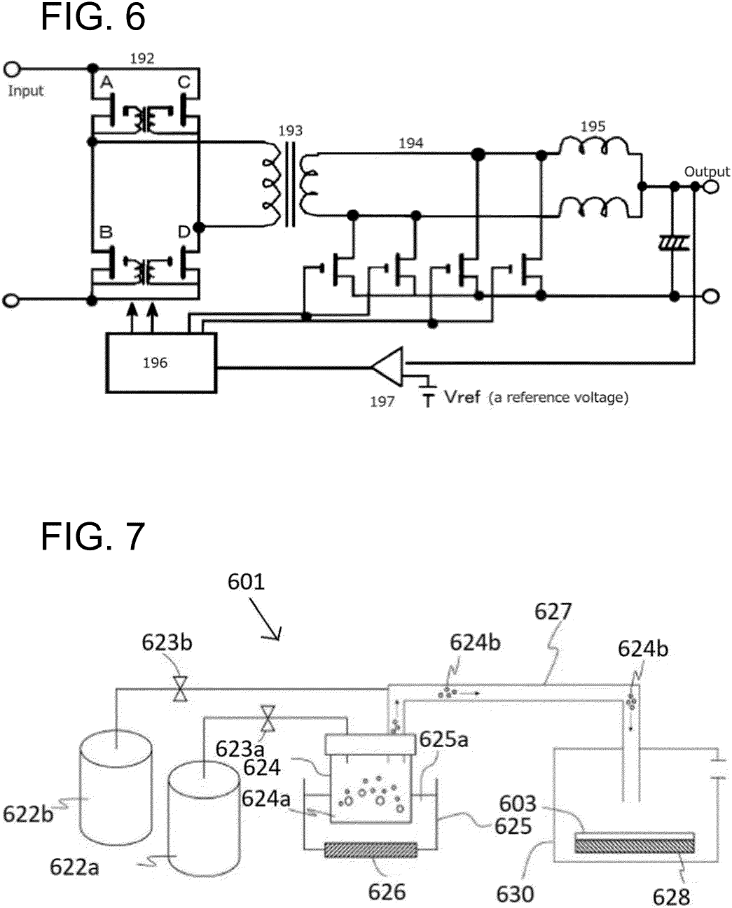

In addition to the abovementioned features, by further using a well-known method, the semiconductor device of the present disclosure is suitably used as a power module, an inverter, or a converter, and is further suitably used in a semiconductor system using a power source apparatus, for example. It is possible to produce the power source apparatus from the semiconductor device or as the semiconductor device by connecting the power source apparatus to a wiring pattern and the like with use of a well-known method. FIG. 4 configures a power source system 170 with use of a plurality of power source apparatuses 171, 172 described above and a control circuit 173. As illustrated in FIG. 5, the power source system is usable in a system apparatus 180 by combining an electronic circuit 181 and a power source system 182. One example of a power source circuit diagram of the power source apparatus is illustrated in FIG. 6. FIG. 6 illustrates a power source circuit of the power source apparatus formed by a power circuit and a control circuit. DC voltage is converted to AC by performing switching at a high frequency by an inverter 192 (configured by MOSFETs A to D). Then, insulation and transformation are performed by a transformer 193, and rectification is performed by a rectification MOSFET 194 (A-B′). Then, smoothing is performed by a DCL 195 (smoothing coils L1, L2) and a capacitor, and DC voltage is output. At this time, the output voltage is compared with reference voltage by a voltage comparator 197, and the inverter 192 and the rectification MOSFET 194 are controlled by a PWM control circuit 196 such that desired output voltage is obtained.

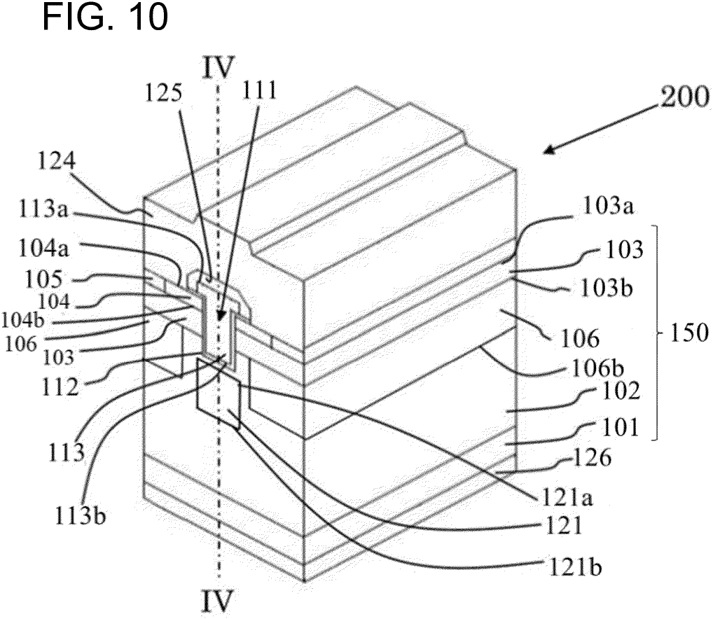

In the present disclosure, it is preferred that the semiconductor device be a power card. It is more preferred that the semiconductor device include a cooler and an insulation member, and the cooler be provided on each of both sides of the semiconductor layer via at least the insulation member. It is most preferred that a heat release layer be provided on each of both sides of the semiconductor layer, and the cooler be provided on the outer side of the heat release layer via at least the insulation member. FIG. 9 illustrates a power card that is one preferred embodiment of the present disclosure. The power card in FIG. 9 is a both-plane-cooling-type power card 201 and includes refrigerant tubes 202, spacers 203, insulating plates (insulating spacers) 208, a sealing resin portion 209, a semiconductor chip 301a, a metal heat transfer plate (protruding terminal portion) 302b, a heat sink, an electrode 303, a metal heat transfer plate (protruding terminal portion) 303b, a solder layer 304, a control electrode terminal 305, and bonding wire 308. The cross-section of each of the refrigerant tubes 202 in the thickness direction has a large number of flow paths 222 partitioned by a large number of dividing walls 221 extending in the flow path direction so as to be spaced apart from each other at a predetermined interval. According to such suitable power card, it becomes possible to realize higher heat release property and satisfy higher reliability.

The semiconductor chip 301a is joined onto a principal plane on the inner side of the metal heat transfer plate (protruding terminal portions) 302b by a solder layer 304, and the metal heat transfer plate (protruding terminal portion) 303b is joined to the remaining principal plane of the semiconductor chip 301a by the solder layer 304. As a result, an anode electrode plane and a cathode electrode plane of a flywheel diode are connected to a collector electrode plane and an emitter electrode plane of the IGBT in a so-called antiparallel manner. Examples of the material of the metal heat transfer plates (protruding terminal portions) 302b and 303b include Mo or W. The metal heat transfer plates (protruding terminal portions) 302b and 303b have a difference in thickness that absorbs the difference in thickness between semiconductor chips 301a. As a result, outer surfaces of the metal heat transfer plates 302b and 303b become planar surfaces.

The sealing resin portion 209 is formed by epoxy resin, for example, and is molded so as to cover side planes of the metal heat transfer plates 302b and 303b. The semiconductor chip 301a is molded with the sealing resin portion 209. However, outer principal planes, in other words, contact heat-receiving planes of the metal heat transfer plates 302b and 303b are fully exposed. The metal heat transfer plates (protruding terminal portions) 302b and 303b protrude to the right side in FIG. 9 from the sealing resin portion 209. The control electrode terminal 305 that is a so-called lead frame terminal connects the control electrode terminal 305 and a gate (control) electrode plane of the semiconductor chip 301a on which the IGBT is formed, for example.

The insulating plates 208 that are insulating spacers are configured by aluminum nitride film, for example, but may be other insulating films. The insulating plates 208 completely cover the metal heat transfer plates 302b and 303b in close contact therewith. However, the insulating plates 208 and the metal heat transfer plates 302b and 303b may simply be in contact with each other, a material with satisfactory heat transfer property such as silicone grease may be applied, or the insulating plates 208 and the metal heat transfer plates 302b and 303b may be joined to each other by various methods. An insulating layer may be formed by ceramic spraying and the like, or the insulating plates 208 may be joined onto the metal heat transfer plates or may be joined onto or formed on the refrigerant tubes.

The refrigerant tube 202 is produced by cutting a plate material obtained by performing pultrusion molding or extrusion molding of an aluminum alloy into necessary lengths. The cross-section of each of the refrigerant tubes 202 in the thickness direction has a large number of the flow paths 222 partitioned by a large number of the dividing walls 221 extending in the flow path direction so as to be spaced apart from each other at a predetermined interval. The spacers 203 may be soft metal plates of a solder alloy and the like, but also may be films formed by application and the like onto contact planes of the metal heat transfer plates 302b and 303b. The surface of each of the soft spacers 203 easily deforms and reduces thermal resistance by fitting with minute unevenness and a warp of the insulating plate 208 and minute unevenness and a warp of the refrigerant tube 202. Well-known grease with satisfactory thermal conductivity and the like may be applied to the surface and the like of each of the spacers 203, or the spacers 203 may be omitted.

The embodiments of the present invention are exemplified in all respects, and the scope of the present invention includes all modifications within the meaning and scope equivalent to the scope of claims.

### Industrial Applicability

The semiconductor device of the present disclosure is usable in any field such as compound semiconductor electronic devices, electronic components, electromechanical components, optical and electronic photography related apparatuses, and industrial components, for example, but is particularly suitable for use in a power device including an oxide semiconductor layer.

### Reference Signs List

1 n+-type semiconductor layer
2 n--type semiconductor layer
3 Gate electrode
3a Buried lower end portion
6 p+-type semiconductor layer (deep p layer)
7 p--type semiconductor layer (channel layer)
11 n+-type semiconductor layer
13 Gate insulating film
16 p+-type semiconductor layer
24 Source electrode
25 Interlayer insulating film
26 Drain electrode
27 p-type semiconductor layer
28 i-type semiconductor layer
101 First crystalline oxide semiconductor layer
102 Second crystalline oxide semiconductor layer
103 Third crystalline oxide semiconductor layer
103a First plane of third crystalline oxide semiconductor layer
103b Second plane of third crystalline oxide semiconductor layer
104 First semiconductor region
104a First plane of first semiconductor region
104b Second plane of first semiconductor region
105 Second semiconductor region
106 Deep p layer in outer position
106b Buried lower end portion of deep p layer
111 Trench
112 Insulating film
113 Gate electrode
113a Upper end portion of gate electrode
113b Buried lower end portion of gate electrode
121 Heat release portion
122 Second concentration region
123 First concentration region
124 Source electrode
125 Insulating film (interlayer insulating film)
126 Drain electrode
150 Laminated body
170 Power source system
171 Power source apparatus
172 Power source apparatus
173 Control circuit
180 System apparatus
181 Electronic circuit
182 Power source system
192 Inverter
193 Transformer
194 Rectification MOSFET
195 DCL
196 PWM control circuit
197 Voltage comparator
200 Semiconductor device
300 Semiconductor device
400 Semiconductor device
500 Semiconductor device
201 Both-plane-cooling-type power card
202 Refrigerant tube
203 Spacer
208 Insulating plate (insulating spacer)
209 Sealing resin portion
221 Dividing wall
222 Flow path
301a Semiconductor chip
302b Metal heat transfer plate (protruding terminal portion)
303 Heat sink and electrode
303b Metal heat transfer plate (protruding terminal portion)
304 Solder layer
305 Control electrode terminal
308 Bonding wire
601 Mist apparatus (film formation apparatus)
602 Mist apparatus (film formation apparatus)
603 Substrate
621 Susceptor
622a Carrier gas supplying apparatus
622b Carrier gas (diluted) supplying apparatus
623a Flow rate regulation valve
623b Flow rate regulation valve
624 Mist generation source
624a Raw material solution
625 Container
625a Water
626 Ultrasonic transducer
627 Supply pipe
628 Heater
629 Exhaust port
630 Film formation chamber

What is claimed is:

1. A semiconductor device, comprising:
a gate electrode having at least a part buried in a semiconductor layer;
a deep p layer having at least a part buried in the semiconductor layer to a same depth as a buried lower end portion of the gate electrode or a position deeper than the buried lower end portion; and
a channel layer, wherein:
the deep p layer is formed by a crystalline oxide semiconductor; and
a carrier concentration of the deep p layer is higher than a carrier concentration of the channel layer.

2. The semiconductor device according to claim 1, wherein a breakdown field strength of the crystalline oxide semiconductor is 5 MV/cm or more.

3. The semiconductor device according to claim 1, wherein the crystalline oxide semiconductor has a corundum structure or a β-gallia structure.

4. The semiconductor device according to claim 1, wherein the crystalline oxide semiconductor is gallium oxide or mixed crystal of gallium oxide.

5. The semiconductor device according to claim 1, wherein the carrier concentration of the deep p layer is 1× 10¹⁷/cm³ or more.

6. The semiconductor device according to claim 1, wherein the semiconductor layer is an n-type semiconductor layer.

7. The semiconductor device according to claim 1, wherein the semiconductor layer is a crystalline oxide semiconductor layer.

8. The semiconductor device according to claim 1, wherein a breakdown field strength of the semiconductor layer is 5 MV/cm or more.

9. The semiconductor device according to claim 1, wherein the semiconductor layer has a corundum structure or a β-gallia structure.

10. The semiconductor device according to claim 1, wherein the semiconductor layer contains gallium oxide or mixed crystal of gallium oxide.

11. A semiconductor device, comprising:
a gate electrode having at least a part buried in a semiconductor layer;
a deep p layer having at least a part buried in the semiconductor layer to a same depth as a buried lower end portion of the gate electrode or a position deeper than the buried lower end portion; and
a channel layer, wherein:
a breakdown field strength of the deep p layer is 5 MV/cm or more; and
a carrier concentration of the deep p layer is higher than a carrier concentration of the channel layer.

12. The semiconductor device according to claim 1, wherein the semiconductor layer has a thickness of 30 µm or less.

13. The semiconductor device according to claim 1, wherein at least a part of a heat release portion is provided in a depth position of the buried lower end portion of the deep p layer in the semiconductor layer.

14. A semiconductor device, comprising:
a gate insulating film and a gate electrode each having at least a part buried in an n-type semiconductor layer;
a first deep p layer and a second deep p layer each having at least a part buried in the semiconductor layer to a same depth as a buried lower end portion of the gate electrode or a position deeper than the buried lower end portion; and
a channel layer, wherein:
the gate insulating film and the gate electrode are provided on an upper side between the first deep p layer and the second deep p layer;
both of the deep p layers are formed by a crystalline oxide semiconductor; and
a carrier concentration of each of the deep p layers is higher than a carrier concentration of the channel layer.

15. The semiconductor device according to claim 1 that is a normally-off-type semiconductor device.

16. The semiconductor device according to claim 1 that is a power device.

17. The semiconductor device according to claim 1 that is a power module, an inverter, or a converter.

18. The semiconductor device according to claim 1 that is a power card.

19. A semiconductor system, comprising a semiconductor device, wherein the semiconductor device is the semiconductor device according to claim 1.
